(19) United States
(12) Patent Application Publication
(10) Pub. No.: US 2009/0050051 A1
(43) Pub. Date: Feb. 26, 2009

(54) Method for Growing Thin Semiconductor Ribbons

(76) Inventor: Claude Remy, Limonest (FR)

Correspondence Address: SOFER & HAROUN LLP., 317 MADISON AVENUE, SUITE 910, NEW YORK, NY, 10017, US

(21) Appl. No.: 11/884,242

(22) PCT Filed: Mar. 1, 2006
(86) PCT No.: PCT/FR2006/050185

§ 371 Date: Sep. 15, 2008

(30) Foreign Application Priority Data
Apr. 22, 2005 (FR) 0551032

(51) Int. Cl. C30B 15/34

(52) U.S. Cl. 117/24

(57) ABSTRACT

A method of pulling at least one ribbon of a semiconductor material, in which method two parallel filaments that are spaced apart from each other pass vertically upwards through the surface of a melt of said semiconductor material in a continuous manner, said ribbon being formed from a meniscus located between said filaments and substantially at said surface. According to the invention, a support strip is interposed between said filaments and is contained in the plane defined by said filaments, said support strip passing vertically upwards through said surface of said melt of molten semiconductor material in a continuous manner at the same rate as said filaments, said ribbon of semiconductor material being formed on one of the two faces of said support strip and being supported by said face. The invention can be used for making polycrystalline silicon ribbons for fabricating photo-cells.

The present invention relates to a method of pulling thin ribbons of semiconductor, in particular polycrystalline silicon, from a melt of silicon.

### BACKGROUND OF THE INVENTION

The most widely used semiconductor ribbons, in particular for the production of photovoltaic cells, are ribbons of polycrystalline silicon. Thus, the following description refers to silicon ribbons but it should be borne in mind that the invention also relates to ribbons of other semiconductor materials such as germanium or gallium arsenide.

When fabricating photovoltaic cells, producing thin ribbons of silicon is a solution that is preferred over producing wafers of silicon by sawing ingots. The ribbon solution substantially reduces the consumption of silicon, does away with the expensive wafer sawing operation, and reduces the consumption of toxic chemicals.

Of the numerous solutions to growing or pulling ribbons of silicon which have been developed, two vertical pulling methods have proved to be the best for producing thin ribbons; one, termed “RST” for Ruban sur substrat temporaire (ribbon on temporary substrate) and the other termed “STR” (String Ribbon).

In the RST method, a thin strip which is generally made of carbon moves vertically upwards at a constant rate through a melt of silicon. A thin layer of silicon is deposited on each of the two faces of the carbon strip. After solidification, the strip leaving the melt is a composite strip constituted by a carbon core inserted between two layers of silicon. The carbon core is subsequently eliminated by burning in a high temperature furnace. Two thin silicon strips are obtained which are cut into wafers. The RST method is described, for example, in French patents FR-A-2 386 359, FR-A-2 550 965, and FR-A-2 561 139.

The other method, the STR method, is shown diagrammatically in FIG. 1. A pulling crucible 10 provided with heater means (not shown) contains a silicon melt 12. The base of the crucible is pierced by two orifices through which two filaments 14 and 16 penetrate; they are parallel, vertical, and spaced from each other. Said filaments move at a constant rate upwards through the silicon. A seed can initiate crystallization of the silicon between the two filaments at the surface of the silicon melt. A self-supported ribbon 18 may then be pulled between the two filaments which act to stabilize or anchor the edges of the ribbon. The ribbon 18 grows from the meniscus 20 which forms by capillary flow over a height of about 7 mm [millimeter] above the surface of the silicon melt between the filaments 14 and 16. After solidification of the silicon, the filaments are incorporated into the silicon ribbon at its edges. International patent application WO-A-2004/035877, for example, describes an implementation of the STR method and means that can reduce or prevent the deformation of the meniscus as sometimes occurs.

Although they perform well, such vertical pulling methods suffer from problems with instability of the liquid silicon meniscus at each end of the ribbon due to capillary forces that tend to divide that meniscus. Various improvements to the method have been proposed. As an example, for the RST method, FR-A-2 550 965 proposes the use of fixed elements placed near the edges of the ribbon to adjust the shape of the meniscus and the thickness of the silicon layer over those edges. Similarly, for the STR method, WO-A3-01/04388 proposes means for stabilizing the edge of the meniscus by raising the level of the silicon melt near the filaments. However, such solutions are not entirely satisfactory.

The STR method has other disadvantages. As an example, its productivity is low because of the low pulling rate, of the order of 1.7 cm/min [centimeter/minute]. Above that pulling rate, the ribbon distorts due to thermal stresses which deform the surface of the silicon ribbon. Proposals have thus been made to carry out a plurality of parallel pulling procedures in the same apparatus. However, parallel pulling encounters the problem of interference between the free liquid meniscuses. In fact, the meniscuses tend to attract each other to reduce surface energy, which results in defects in the planarity of the ribbons. That problem is partially solved in International patent application WO-A1-2004/042122, at the price of rendering the method more complex, by placing elements around the ribbons to control the shape of the meniscus in the lateral portion of the ribbon. Another disadvantage of the STR system resides in the fact that in practice, it is difficult to produce a ribbon less than 250 μm [micrometers] thick. Below that thickness, the silicon ribbon becomes distorted and fragile and is difficult to manipulate during steps of photovoltaic cell fabrication. Further, the STR method comprises a seeding stage for initiation that is critical and difficult on starting pulling the ribbon or re-starting following accidental rupture of the liquid meniscus.

### OBJECT AND SUMMARY OF THE INVENTION

The aim of the present invention is to improve the STR method by overcoming one or more of the disadvantages mentioned above.

To this end, the invention provides a method of pulling at least one ribbon of a semiconductor material in which method two parallel filaments that are spaced apart from each other pass vertically upwards through the surface of a melt of said semiconductor material in a continuous manner, said ribbon being formed from a meniscus located between said filaments and substantially at said surface. According to the invention, a support strip is interposed between the filaments and is contained in the plane defined by the filaments, the support strip passing vertically upwards through the surface of the melt of molten semiconductor material in a continuous manner at the same rate as the filaments, the ribbon of semiconductor material being formed on one of the two faces of the support strip and being supported by said face.

Preferably, two ribbons of semiconductor material are formed simultaneously, one on one of the two faces of the support strip and the other on the other face.

Advantageously, the filaments are made of carbon or silica and have a diameter in the range 0.3 mm to 1 mm. They may be covered with a thin layer of pyrolytic graphite.

In a preferred implementation, the support strip is made of carbon and is in the range 200 micrometers to 350 micrometers thick. The molten semiconductor material is contained in a pulling crucible provided with a substantially horizontal base, said base including an aperture through which the support strip and the filaments penetrate.

The aperture preferably has a rectangular horizontal section with a width slightly greater than the thickness of the support strip and, at each of the two ends of the rectangular section, a horizontal circular cross section through which the filaments pass.

The semiconductor material may be based on a semiconductor element such as silicon or germanium or on a congruent or semi-congruent melting semiconductor, such as gallium arsenide.

### BRIEF DESCRIPTION OF THE DRAWING

Other advantages and characteristics of the invention become apparent from the following description of an implementation of the invention given by way of non-limiting example and made with reference to the accompanying drawings in which:

FIG. 1 diagrammatically shows the prior art STR method;

FIG. 2 illustrates the method of the present invention;

FIGS. 3 and 4 show, in horizontal section in horizontal planes at the heights indicated respectively by III and IV in FIG. 2, the two filaments and the two ribbons of semiconductor, in this example silicon, surrounding the carbon support strip; and

FIG. 5 diagrammatically shows, in a horizontal section, the aperture in the pulling crucible through which the support strip and filaments pass.

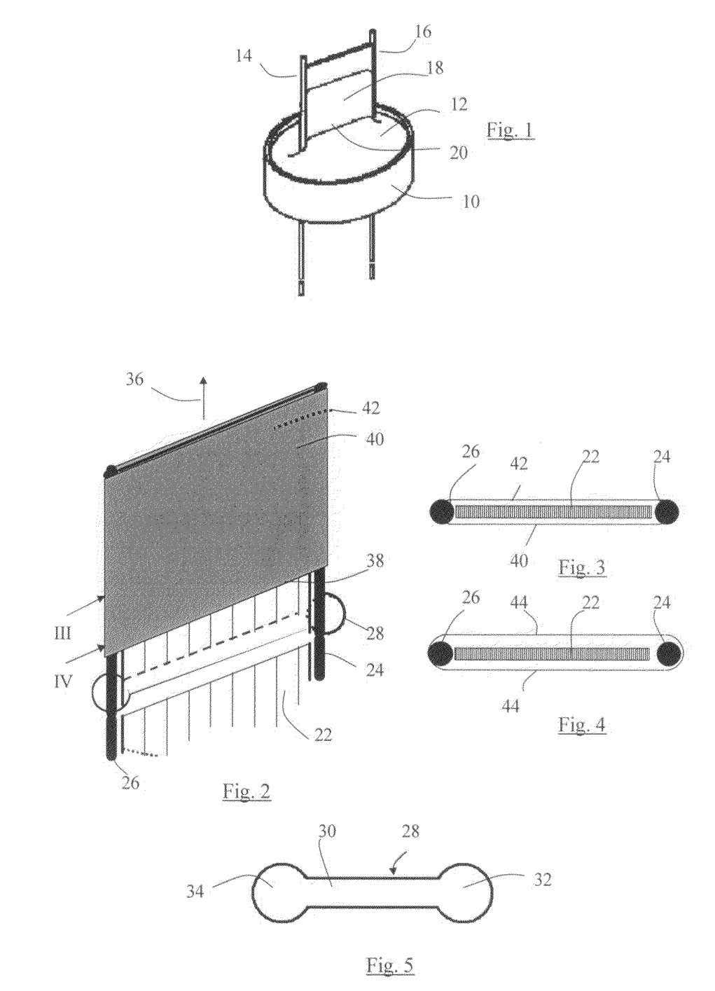

### MORE DETAILED DESCRIPTION

According to the invention, a support strip, preferably made of carbon, is used in the STR method, while also retaining the two carbon filaments. The support strip reinforces anchoring of the meniscus of liquid silicon on the edges of the strip by wetting.

FIG. 2 shows a vertical support strip 22 between two vertical filaments 24 and 26 passing upwards through a pulling crucible (not shown) via an aperture 28 located in the base of the crucible. The pulling crucible, produced from silica or carbon, for example, is filled with silicon which has been rendered liquid by raising its temperature. The support strip is contained in the vertical plane defined by the two longitudinal axes of symmetry of the filaments 24 and 26 (which are substantially prismatic in shape but are not necessarily circularly symmetrical; for example, a rectangular cross section is possible). This aperture 28, also shown in horizontal section in FIG. 5, has the shape of an elongated rectangle 30 terminated at each of its two ends by a circular surface 32 or 34. Rectangle 30 is slightly greater than the width of the support strip 22 and the diameter of the circular surfaces 32 and 34 is slightly larger than the diameter of the filaments so that the support strip 22 and the two filaments 24 and 26 pass through the aperture 28. The distance separating the edges of the aperture 28 from the support strip 22 and the filaments 24, 26 is such that the molten silicon contained in the crucible does not flow through the aperture. As an example, for a support strip thickness of 300 micrometers, for a filament diameter of 0.6 mm and for a height of 1 cm [centimeter] of molten silicon contained in the crucible directly above the aperture, the width of the rectangular section 30 of the aperture may be of the order of 600 μm and the diameter of the circular sections 32, 34 may be of the order of 1 mm.

The support strip 22 and filaments 24, 26 pass through the aperture 28 and pass vertically upwards through the pulling crucible filled with liquid silicon. Means (not shown) pull the assembly formed by the strip 22 and the filaments 24, 26 vertically at a constant rate in the direction of the arrow 36. Without the appearance of a distortion on the surfaces of the composite, the pulling rate may reach values close to 5 cm/min for silicon ribbons that are about 200 μm thick, and close to 10 cm/min for ribbons that are about 80 μm thick. By comparison, the maximum pulling rate in the conventional STR method is about 1.7 cm/min, i.e. about 3 to 6 times slower.

A meniscus forms at the junction 38 of the surface of the liquid silicon with the support strip 22 and the filaments 24, 26. The two sides of the support strip 22 are coated with a thin layer of silicon which crystallizes on cooling. Thus, two ribbons 40 and 42 of polycrystalline silicon are obtained simultaneously.

FIGS. 3 and 4 show, in cross section in horizontal planes at the heights indicated respectively by III and IV relative to the silicon melt, the shapes of ribbons 40 and 42 adhering to the support strip 22 and to the filaments 24, 26. At plane III, the silicon has cooled and crystallized to form ribbons of silicon, while at plane IV, a few millimeters (typically less than 6 mm) above the surface of the molten silicon, the silicon 44 has not yet solidified and forms a meniscus.

In a preferred implementation, the filaments 24 and 26 are identical, produced from carbon or silica, optionally coated with pyrolytic graphite, and their diameter is in the range 0.3 mm to 1 mm. They are separated from the edges of the support strip 22 by about 100 μm to prevent any contact that may deform the support strip.

The support strip 22 is in the range 200 μm to 350 μm thick, preferably in the range 200 μm to 300 μm. This support strip is preferably produced from carbon, for example flexible graphite produced from natural, expanded, and then rolled graphite. The support strip 22 may be supplied in rolls a meter wide and several tens of meters long. However, for the implementation described here, a width in the range 5 cm to 20 cm, for example, is preferably used.

After pulling, a composite strip obtained is constituted by the support strip 22, the two filaments 24, 26, and the two silicon ribbons 40, 42 supported by the support strip and the filaments. The next step consists initially, using a laser, for example, in cutting the composite strip into composite wafers, which are generally rectangular, and cutting the edges of the composite strip or composite wafers to expose the side edge of the carbon ribbons. The filaments 24, 26 are thus eliminated. Next, the support strip 22 is destroyed by burning, for example in air, at high temperature (about 1000° C.) to obtain two wafers of polycrystalline silicon. The faces of the wafers, which have been freed or which are located facing the support strip, then undergo low level stripping to eliminate the oxidized layer formed on the surface from the silica. Said oxidized layer is very thin, of the order of a few tens of micrometers. Stripping may be carried out using various conventional techniques.

The modifications to the STR method described above can improve the productivity of the conventional method by a higher pulling rate and by the simultaneous production of two ribbons of silicon, can reduce the consumption of silicon by reducing the thickness of the ribbons to values below 100 μm, and can improve the planarity of the ribbons. This advantage of planarity is due to a number of effects. Firstly, the thermophysical characteristics of the support strip provide additional advantages to the conventional STR method using two filaments, which avoids or minimizes the formation of a composite strip with distorted surfaces. Participation of the support strip in extracting the latent heat of crystallization reduces the relative temperature gradient in the strip of silicon at the crystallization front, which retards the appearance of the phenomenon of buckling due to thermomechanical stresses and allows very high pulling rates to be used; further, its thermal inertia stabilizes the thermal field close to the meniscus, thereby reducing displacement of the crystallization isotherm. Furthermore, the presence of a support strip in the pulling crucible halves the width of the silicon melt, which attenuates thermal convection currents that tend to develop in the melt, and also attenuates displacement of the crystallization isotherm which they may induce. Further, the presence of the support strip considerably reduces the possibility of displacement of the crystallization meniscus due to disturbance it suffers due to variations in the angle connecting the liquid surface with the walls of the pulling crucible and/or to the presence of a nearby meniscus when several ribbons are being pulled simultaneously from the same silicon melt. The presence of the support strip physically maintains the attachment point of the liquid meniscus in a quasi fixed vertical plane, with the possibility of displacement in a direction perpendicular to the support strip of being typically less than ±100 μm.

Thus, compared with the conventional STR method, the present invention can produce ribbons of silicon that are thinner, for example less than 150 μm thick, with better planarity, and at higher pulling rates (and thus with a higher productivity). Thus, the invention is particularly suitable to producing photovoltaic cells by using the silicon ribbons produced.

Obvious modifications or variations may be made by the skilled person to the method described above without departing from the scope of the present invention. As an example, a single ribbon may be produced instead of two at once, by preventing silicon from being deposited on one of the two faces of the support strip. Furthermore, it is easy to envisage the support strip and the two filaments not penetrating into the silicon melt through the bottom of the apparatus, but through a side wall or entering the melt directly from the top and passing via a return mechanism so as to leave through the top of the melt.

1. A method of pulling at least one ribbon of a semiconductor material, said method comprising the steps of:
passing two parallel filaments that are spaced apart from each other pass vertically upwards through the surface of a melt of said semiconductor material in a continuous manner, said ribbon being formed from a meniscus located between said filaments and substantially at said surface, wherein a support strip is interposed between said filaments and is contained in the plane defined by said filaments, and wherein said support strip passing vertically upwards through said surface of said melt of molten semiconductor material in a continuous manner at the same rate as said filaments, said ribbon of semiconductor material being formed on one of the two faces of said support strip and being supported by said face.

2. A method according to claim 1, wherein two ribbons of semiconductor material are formed simultaneously, one on one of the two faces of said support strip and the other on the other face.

3. A method according to claim 1, wherein said filaments are made of carbon or silicon.

4. A method according to claim 3, wherein the diameter of said filaments is in the range 0.3 mm to 1 mm.

5. A process according to claim 3, wherein said filaments are coated with a thin layer of pyrolytic graphite.

6. A method according to claim 1, wherein said support strip is made of carbon.

7. A method according to claim 6, wherein the thickness of said support strip is in the range 200 μm to 300 μm.

8. A method according to claim 1, wherein the ribbon of semiconductor material is less than 250 μm thick.

9. A method according to claim 1, wherein said molten semiconductor material is contained in a pulling crucible provided with a substantially horizontal base, said base including an aperture via which said support strip and said filaments penetrates.

10. A method according to claim 9, wherein said aperture has a rectangular horizontal section the width of which is slightly greater than the thickness of said support strip and, at each of the two ends of the rectangular section, it has a circular horizontal section through which said filaments pass.

11. A method according to claim 1, wherein said semiconductor material is based on a semiconductor element or a congruent or quasi-congruent melting semiconductor compound.

12. A method according to claim 11, wherein said semiconductor material is silicon.

13. A method according to claim 1, wherein the edges of the support strip are separated from the filaments by at least 100 micrometers to prevent any contact which may deform said support strip.
